(19) United States
(12) Patent Application Publication
(10) Pub. No.: US 2006/0219546 A1
(43) Pub. Date: Oct. 5, 2006

(54) Concentration-graded alloy sputtering target

(76) Inventors: Chia-Hong Jan, Portland, OR (US); Brett R. Schroeder, Portland, OR (US); Robert I. Wu, Ladera Ranch, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/097,620

(22) Filed: Mar. 31, 2005

(51) Int. Cl. C23C 14/32; C23C 14/00

(52) U.S. Cl. 204/192.1; 204/298.12

(57) ABSTRACT

A sputtering target comprising a concentration-graded alloy is utilized to achieve a uniform seed layer across a microelectronic wafer for the formation of microelectronic device interconnects. The concentration-graded alloy sputtering target achieves the substantially uniform seed layer by counteracting the affects of a sputtering system which would normally result in a non-inform seed layer if a single/uniform concentration sputtering target were used.

### BACKGROUND OF THE INVENTION

1. Field of the Invention

An embodiment of the present invention relates to microelectronic device fabrication. In particular, an embodiment of the present invention relates to a concentration-graded alloy target and methods of fabricating seed layers for microelectronic interconnects utilizing the same.

2. State of the Art

The microelectronic device industry continues to see tremendous advances in technologies that permit increased integrated circuit density and complexity, and equally dramatic decreases in package sizes. Present microelectronic technology now permits single-chip microprocessors with many millions of transistors, operating at speeds of tens (or even hundreds) of MIPS (millions of instructions per second), to be packaged in relatively small, air-cooled microelectronic device packages. These transistors are generally connected to one another or to devices external to the microelectronic device by conductive traces and vias (hereinafter collectively referred to as “interconnects”) through which electronic signals are sent and/or received.

One process used to form contacts is known as a “damascene process”. In a typical damascene process, a photoresist material is patterned on a dielectric material layer, which is etched through the photoresist material patterning to form a hole or trench extending at least partially through the first dielectric material layer. The photoresist material is then removed and a barrier layer is deposited within the hole or trench on sidewalls and a bottom surface thereof. The barrier layer prevents conductive material (particularly copper and copper-containing alloys), which will subsequently be deposited into the hole or trench, from migrating into the first dielectric material layer, which can adversely affect the quality of microelectronic device, such as leakage current and reliability between interconnects, as will be understood to those skilled in the art.

A seed layer, which provides a nucleation site for a subsequent electroplating step, is deposited on the barrier layer. Seed layers are generally formed by a physical vapor deposition process, also known as sputtering. Sputtering is a process where a plasma is struck in an inert gas. Ions formed in the plasma collide with a target. Material is ejected from the surface of the target and deposits on the wafer, thereby forming the seed layer. This sputtering process is usually carried out in a diode plasma system known as magnetron, as will be discussed below.

After the formation of the seed material, the hole or trench is filled, usually by an electroplating process, with the conductive material to form a conductive material layer. The resulting structure is planarized, usually by a technique called chemical mechanical planarization (CMP) to remove any conductive material layer and any barrier layer that is not within the hole or trench from the surface of the dielectric material, to form an interconnect.

Although the above described process is effective in the formation of interconnects, one problem has arisen with the use of large microelectronic wafers. This problem is poor uniformity of seed layer concentration across the microelectronic wafers, particularly on 300 mm microelectronic wafers with sub-0.1 um interconnects. FIG. 12 illustrates a simplified magnetron sputtering system. The magnetron sputtering system 300 comprises a vacuum chamber 302 that contains a target 304, a substrate 306 (i.e., wafer) on a wafer chuck 308, and a magnetron (magnet) 312 (external to the vacuum chamber 302). The vacuum chamber 302 is first evacuated and backfilled with an inert gas, such as argon. A plasma 314 is struck in the chamber, either by RF or DC power, as will be understood to those skilled in the art, to generate gas ions, such as Ar+ ions. The target 304 is biased as a cathode such that the gas ions are attracted to and strike the target 304. The collision of the gas ions with the target 304 ejects target atoms therefrom, which deposit on the substrate 306, and in this example, forms a seed layer (not shown). To increase the deposition rate, the magnetron 312 is placed above the target 304 (external from the vacuum chamber 302) to improve the frequency of gas molecule collisions in the formation of the plasma 314. However, the plasma 314 generated in a magnetron sputtering system 300 does not form in manner that results in a uniform deposition of the target atoms on the substrate 306. Generally, as shown in FIGS. 13 and 14 (on a 300 mm wafer, such as a substrate 306 (see FIG. 12)), the target ions are deposited more densely at a center 316 of the wafer (substrate 306—FIG. 12) than at an edge 318 thereof. FIG. 13 illustrates an exemplary contour plot for a normalized thickness of a seed layer on a wafer and FIG. 14 illustrates a normalized radial profile of alloy concentration of a seed layer from the center 316 (i.e., 0 mm) of a wafer to the edge 318 of a wafer (i.e., 150 mm for a 300 mm diameter wafer). This non-uniform deposition results in inferior electromigration performance at the edge 318 of the wafer (substrate 306), as will be understood to those skilled in the art.

Therefore, it would be advantageous to develop a method to deposit a seed layer which is substantially uniform across an entire wafer.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 illustrates a cross-sectional view of a dielectric layer having a resist patterned thereon, according to the present invention;

FIG. 2 illustrates a cross-sectional view of the structure of FIG. 1 with an opening etched into the dielectric layer through the patterned resist, according to the present invention;

FIG. 3 illustrates a cross-sectional view of the structure of FIG. 2 with a barrier layer formed within the opening, according to the present invention;

FIG. 4 illustrates a cross-sectional view of the structure of FIG. 3 with a seed layer disposed over the barrier layer formed within the opening, according to the present invention;

FIG. 5 illustrates a schematic of a sputtering system, according to the present invention;

FIG. 6 illustrates a sputtering target and a substrate, according to the present invention;

FIG. 7 is a chart of alloy concentration across the sputtering target, according to the present invention;

FIG. 8 is a chart of the resulting alloy concentration across the wafer, according to the present invention;

FIGS. 9a-e illustrate cross-sectional views of a process of fabricating a concentration-graded alloy target and a chart of a profile thereof, according to the present invention;

FIG. 10 illustrates a cross-sectional view of the structure of FIG. 4 with a conductive material layer formed within the opening, according to the present invention;

FIG. 11 illustrates a cross-sectional view of the structure of FIG. 10 with excess conductive material layer and excessive barrier layer not within the opening having been removed to form an interconnect, according to the present invention;

FIG. 12 illustrates a schematic of a sputtering system, as known in the art;

FIG. 13 is a normalized plot for alloy concentration on a wafer, as known in the art; and

FIG. 14 is a graph of alloy concentration on a wafer versus radius, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

An embodiment of the present invention relates to the fabrication of a uniform seed layer across a wafer for a microelectronic device interconnect. The uniform seed layer is achieved through the use of a sputtering target which has a concentration profile that counteracts the affect of a sputtering system which would normally result in a non-uniform seed layer if a single/uniform concentration sputtering target were used.

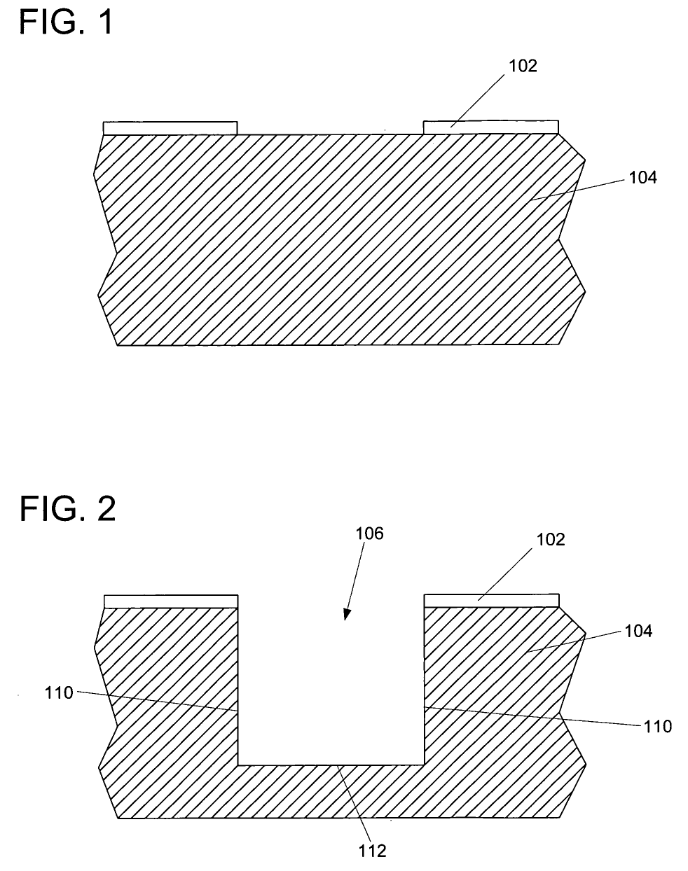

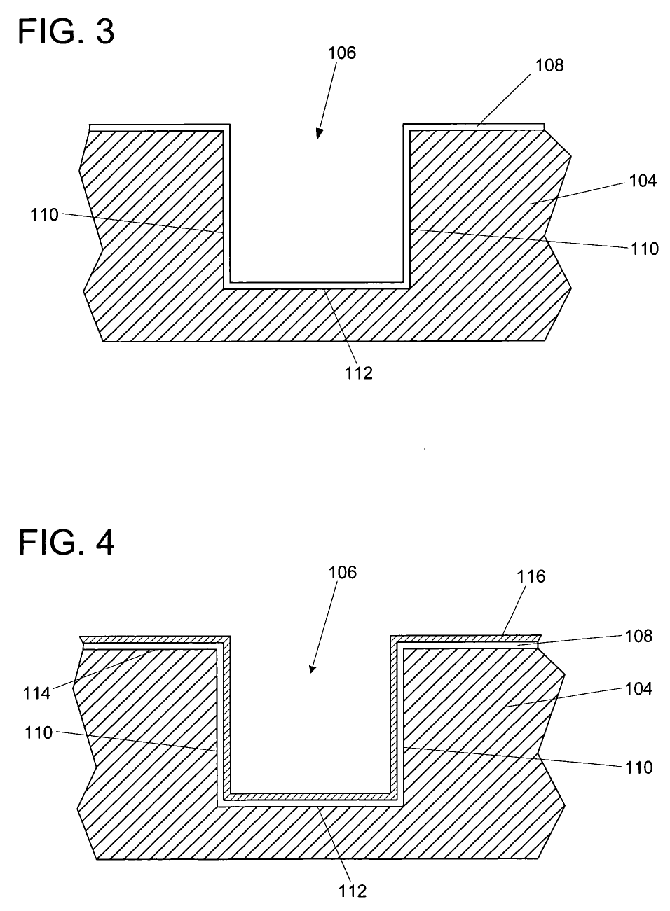

One embodiment of a process used to form an interconnect, according to the present invention, comprises patterning a photoresist material 102 on a dielectric material layer 104 which is on a substrate (not shown), such as a microelectronic wafer, as shown in FIG. 1. The dielectric material layer 104 may include, but is not limited to, silicon dioxide, silicon nitride, carbon doped oxide, and the like. The dielectric material layer 104 is etched through the photoresist material 102 patterning to form a hole or trench 106 (hereinafter referred to collectively as “opening 106”) extending to at least partially through the dielectric material layer 104, as shown in FIG. 2. The photoresist material 102 is then removed (typically by an oxygen plasma) and a barrier layer 108 may be deposited within the opening 106 on sidewalls 110 and a bottom surface 112 thereof to prevent conductive material (particularly copper and copper-containing materials), which will subsequently be deposited into the opening 106, from migrating into the dielectric material layer 104, as shown in FIG. 3. The barrier layer 108 used for copper-containing conductive materials is usually a nitrogen-containing material, including, but not limited to tantalum nitride and titanium nitride. A portion of the barrier layer 108 may also extend over and abut a first surface 114 of the dielectric material layer 104. It is, of course, understood that the opening 106 can be formed by any known technique including, but not limited to, ion milling and laser ablation.

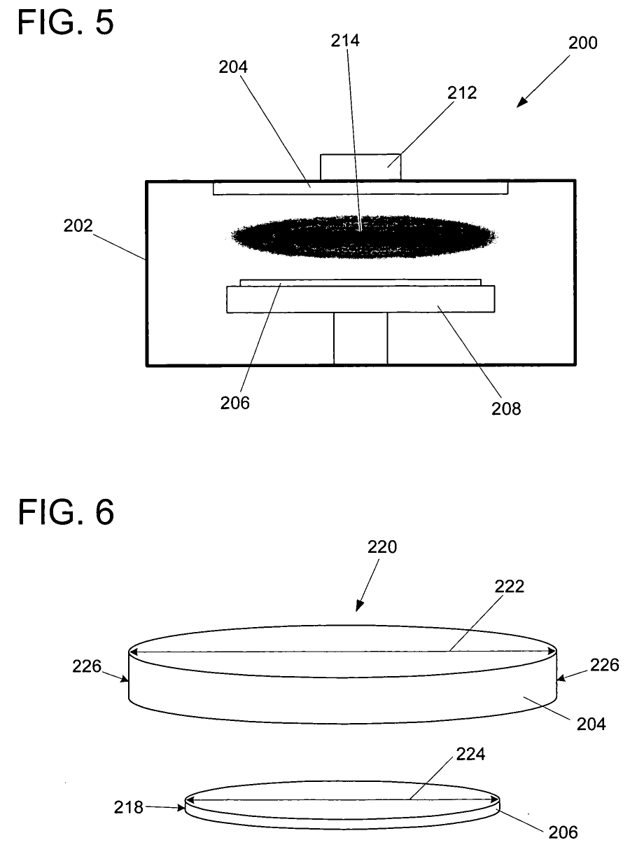

As shown in FIG. 4, a seed material 116 is deposited on the barrier layer 108. The seed material 116 of FIG. 4 may be deposited in a magnetron sputtering system 200, illustrated in FIG. 5. The magnetron sputtering system 200 comprises a vacuum chamber 202 that contains a target 204, a substrate 206 (such as a microelectronic wafer) on a wafer chuck 208, and a magnetron (magnet) 212 (external to the vacuum chamber 202). The vacuum chamber 202 is first evacuated and backfilled with an inert gas, such as argon gas.

A plasma 214 is struck in the vacuum chamber 202, either by RF or DC power, as will be understood to those skilled in the art, to collide gas molecules to generate gas ions, radicals, and electrons. When a potential is placed across the target 204 (biased as a negatively charged cathode) and the wafer chuck 208, with the substrate 206 thereon (biased as a positively charged anode), electrons from the cathode strike the plasma components, stripping them of additional electrons and creating Ar+ ions. The Ar+ ions are attracted to the negatively charged cathode target 204 and collide with the surface of the target 204. The collision of the gas ions with the target 204 impart energy to the atoms of the target 204 thereby ejecting them into the vacuum chamber 202, which deposit on the substrate 206, and in this example, forms the seed layer 116 (shown in FIG. 4). To increase the deposition rate, the magnetron 212 is placed above the target 204 (external from the vacuum chamber 202) to improve the frequency of gas molecule collisions in the formation of the plasma 214. Since atomic collisions of the deposition process results in erosion of the target 204, it is made with a replaceable plate of the material being deposited.

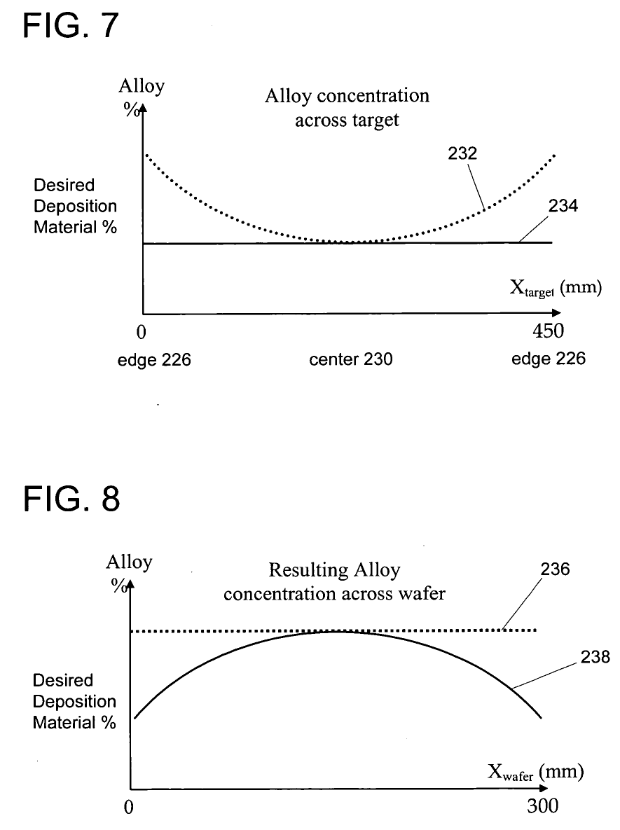

As previously discussed, the plasma 214 generated in the magnetron sputtering system 200 does not form in manner that results in a uniform deposition of the target 204 atoms on the substrate 206, which results in inferior electromigration performance at the edge 218 of the substrate 206, as will be understood to those skilled in the art. To correct this non-uniformity, a concentration-graded alloy sputtering target 220 has been developed. As shown in FIG. 6, the concentration-graded alloy sputtering target 220 may be an alloy material disk generally with larger in diameter 222 (e.g., 450 mm) relative to the substrate 206 diameter 224 (e.g., 300 mm). As shown in FIG. 7, concentration of the desired deposition material within the alloy material varies across the diameter 222 of the concentration-graded alloy sputtering target 220, illustrated with dashed line 232. In specific, the concentration percent of the desired deposition material is greater proximate an edge 226 of the concentration-graded alloy sputtering target 220 (see FIG. 6), illustrated at the 0 mm point and the opposing diameter 450 mm point, than between these two points, such as at a center 230 thereof (e.g., about 225 mm). The concentration gradient 232 is illustrated as substantially a parabolic curve. The prior art uniform concentration is also illustrated as solid line 234 for reference sake. In one embodiment, the desired deposition material is copper which is alloyed with a carrier material, including, but not limited to silver, gold, magnesium, indium, aluminum, tin, titanium, palladium, and platinum. In other embodiment, the desired deposition material is tantalum which is alloyed with a carrier material, including, but not limited to titanium, aluminum, palladium, and platinum. It is, of course understood that the carrier material can be a variety of materials including volatile materials which volatilize into vacuum chamber and do not substantially deposit on the substrate 206, as will be understood to those skilled in the art. The carrier material can be broadly defined as any material in the concentration-graded alloy sputtering target 220 which is not the desired deposition material. Naturally, the desired deposition material concentration at the center of the concentration-graded alloy sputtering target 220, at the edge of concentration-graded alloy sputtering target 220, and the grading profile between the center and the edge, will depend upon the sputtering equipment used, the severity of the non-uniformity, the operating parameters of the sputtering equipment, and the like.

As shown in FIG. 8, when a concentration-grade alloy sputtering target 220 is used with the “non-uniform” sputtering process, the desired deposition material concentration is substantially uniform across the diameter 224, between the 0 mm point and the opposing 300 mm point, of the substrate (wafer), illustrated with dashed line 236. The prior art non-uniform concentration is also illustrated as solid line 238 for reference sake. It is, of course, understood that the concentration profile of the concentration-graded alloy sputtering target 220 must be selected to achieve the substantially uniform deposition material concentration on the substrate 206.

The concentration-graded alloy sputtering target 220 can be fabricated by a number of techniques, including, but not limited to, centrifugal separation, electrical separation, and discrete radial manufacturing. In centrifugal separation, while the alloy material is in a substantially molten or liquid state, the material is spun. The spinning will take advantage of the different masses of the materials within the alloy, wherein the desired deposition material within the alloy will migrate to an edge of the target and, thus, be at a higher concentration proximate the edge. After such separation, the alloy material is allowed to solidify. It is, of course, understood that the materials within the alloy are specifically selected to achieve this desired result. In electrical separation, while the alloy material is in a substantially molten or liquid state, ions of the desired deposition material are created at a higher rate than the carrier material, then an electric field is applied (such as in a radial direction for a circular sputtering target) to drive positive ions of the desired deposition material to the edge of the target and, thus, be at a higher concentration proximate the edge. After such separation, the alloy material is allowed to solidify.

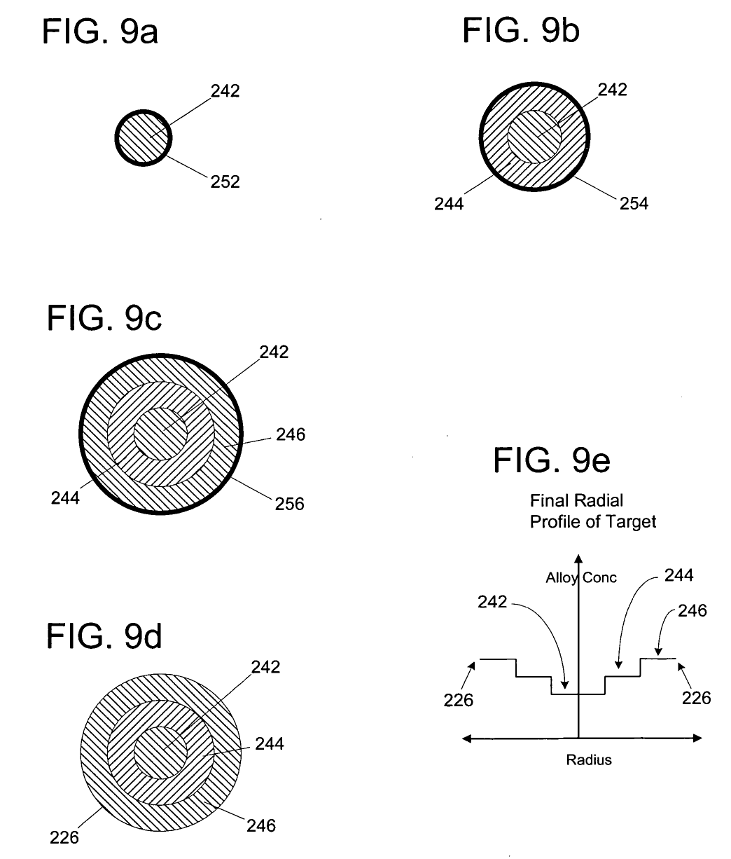

In discrete radial manufacturing, as shown in FIGS. 9a-9d, the target will have discrete regions or rings of uniform concentration. As shown in FIG. 9a, a first target portion 242 is formed by placing a molten or viscous alloy having a first concentration of a desired deposition material in a first mold 252, preferably substantially circular in cross-section. After the first target portion 242 has solidified, it is removed from the first mold 252 and placed (preferably centered) in a second mold 254 (larger than the first mold 252 and preferably substantially circular in cross-section). A molten or viscous alloy having a second concentration of a desired deposition material is deposited between the second mold 254 and the first target portion 242 forming a first annular target portion 244, as shown in FIG. 9b. After the first annular target portion 244 has solidified, it and the first target portion 242 are removed from the second mold 254 and placed (preferably centered) in a third mold 256 (larger than the second mold 254 and preferably substantially circular in cross-section). A molten or viscous alloy having a third concentration of a desired deposition material is deposited between the third mold 256 and the first annular target portion 244 forming a second annular target portion 246, as shown in FIG. 9c. As shown in FIG. 9d, after the second annular target portion 246 has solidified, the concentration-graded alloy sputtering target 220, comprising the first target portion 242, the first annular target portion 244, and the second annular target portion 246, is removed from the second mold 254. The resulting concentration-graded alloy sputtering target 220 will have discrete bands of varying concentration stepping from the center of the concentration-graded alloy sputtering target 220 to an edge 226 thereof, as shown in FIG. 9e. It is, of course, understood that any number of discrete bands can be formed to achieve a desired concentration profile.

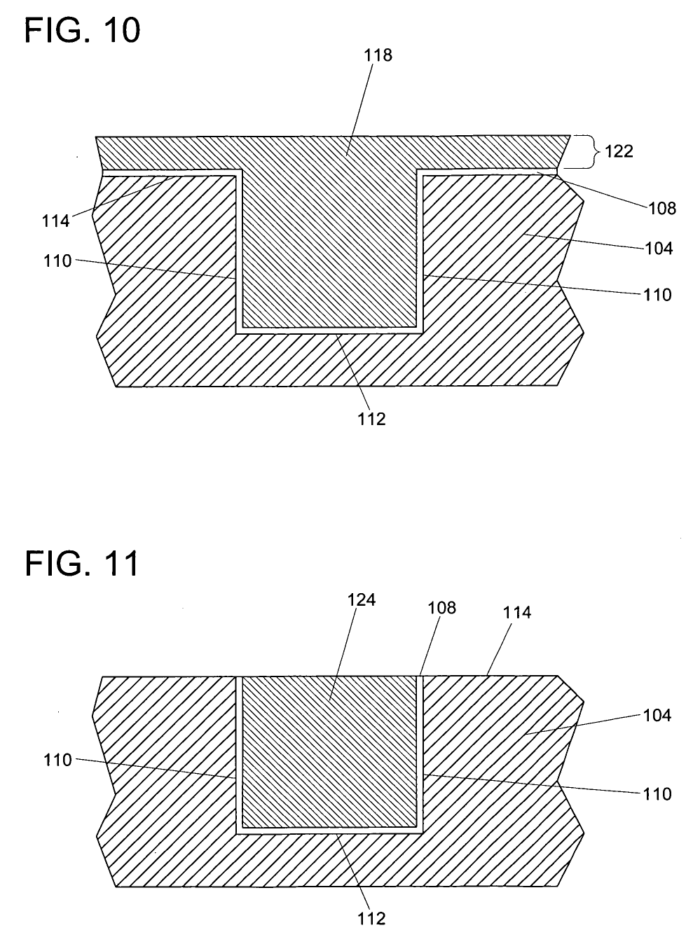

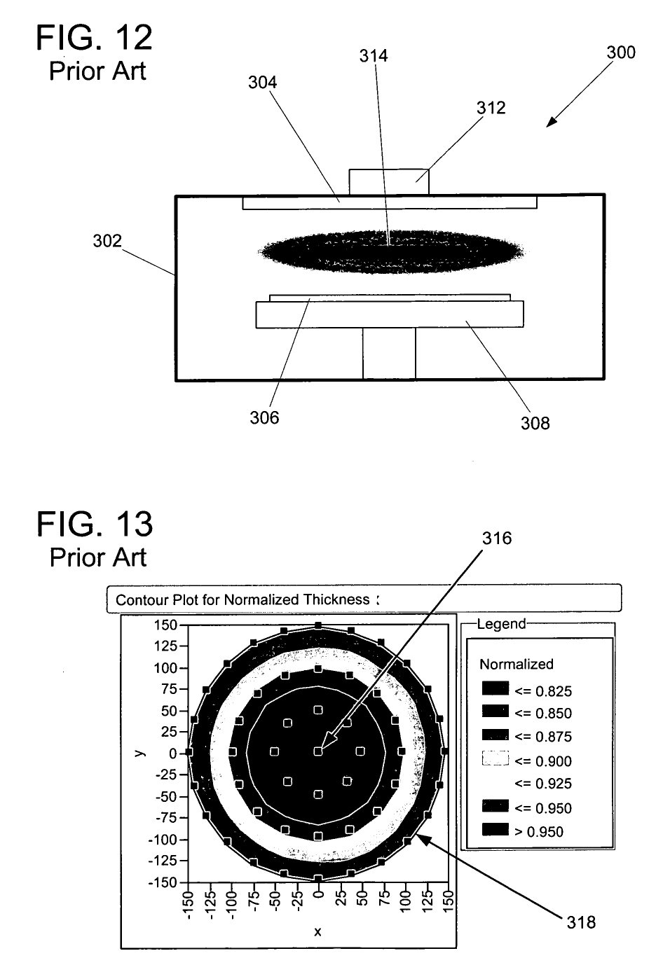

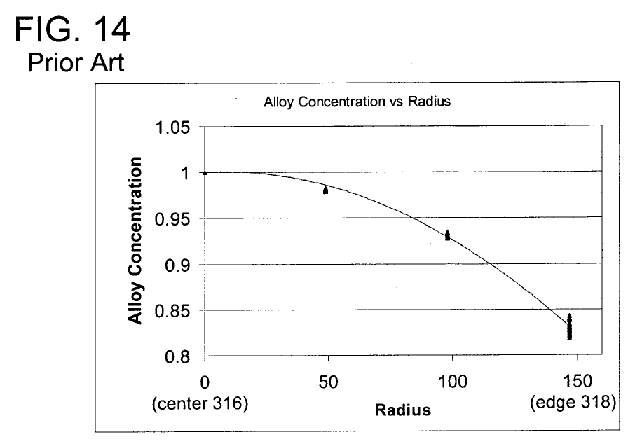

After the formation of the seed layer shown in FIG. 4, the opening 106 is filled with the conductive material, such as copper, aluminum, and alloys thereof, and the like, as shown in FIG. 10, to form a conductive material layer 118. The opening 106 may be filled by any known process, including but not limited to electroplating and the like.

As previously discussed with regard to the barrier layer 108, excess conductive material 122 (e.g., any conductive material not within the opening 106) of the conductive material layer 118 may form proximate the dielectric material layer first surface 114. The resulting structure of FIG. 10 may then be planarized by a process such as chemical mechanical planarization, as shown in FIG. 11, to form an interconnect 124.

Although the present invention is described in terms of depositing a seed layer, it will be understood to those skilled in the art that the concentration-graded alloy sputtering target could be used in any sputtering process wherein uniform material distribution is relevant.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A sputtering target comprising an alloy material having a desired deposition material concentration greater proximate an edge of said sputtering target relative to a center of said sputtering target.

2. The sputtering target of claim 1, wherein said alloy material is substantially circular and wherein said desired deposition material concentration comprises a substantially parabolic curve across a diameter of said substantially circular alloy material.

3. The sputtering target of claim 1, wherein said desired deposition material comprises copper.

4. The sputtering target of claim 1, wherein said desired deposition material comprises tantalum.

5. A method of sputtering a material layer, comprising:
providing a vacuum chamber;
placing a sputtering target, comprising an alloy material having a desired deposition material concentration greater proximate an edge of said sputtering target relative to a center of said sputtering target, within said vacuum chamber;
placing a substrate within said vacuum chamber;
evacuating said vacuum chamber and backfilling said vacuum chamber with an inert gas;
striking a plasma within said vacuum chamber; and
sputtering material from said sputtering target to deposit on said substrate.

6. The method of claim 5, wherein placing said sputtering target, comprising said alloy material having said desired deposition material concentration greater proximate said edge of said sputtering target relative to said center of said sputtering target, within said vacuum chamber comprises placing said sputtering target, comprising a substantially circular alloy material having said desired deposition material with a substantially parabolic concentration curve across a diameter of said substantially circular alloy material, within said vacuum chamber.

7. The method of claim 5, wherein placing said sputtering target, comprising an alloy material having said desired deposition material concentration greater proximate said edge of said sputtering target relative to said center of said sputtering target, within said vacuum chamber comprises placing said sputtering target, comprising an alloy material having a copper deposition material with a substantially parabolic concentration curve across a diameter of said substantially circular alloy material, within said vacuum chamber.

8. The method of claim 5, wherein placing said sputtering target, comprising said alloy material having said desired deposition material concentration greater proximate said edge of said sputtering target relative to said center of said sputtering target, within said vacuum chamber comprises placing said sputtering target, comprising said alloy material having a tantalum deposition material with a substantially parabolic concentration curve across a diameter of said substantially circular alloy material, within said vacuum chamber.

9. The method of claim 5, wherein said sputtering material from said sputtering target to deposit on said substrate comprises sputtering material from said sputtering target to deposit a seed layer on said substrate.

10. The method of claim 9, wherein said sputtering material from said sputtering target to deposit said seed layer on said substrate comprises sputtering material from said sputtering target to deposit said seed layer on a microelectronic wafer.

11. A method of fabricating a concentration-graded alloy sputtering target, comprising:
providing an alloy material in a substantially liquid form including a desired deposition material and a carrier material;
physically separating at least a portion of said desired deposition material to increase a concentration of said desired deposition material at an edge of said alloy material; and
solidifying said alloy material.

12. The method of claim 11, wherein physically separating at least a portion of said desired deposition material comprises spinning said alloy material.

13. The method of claim 11, wherein physically separating at least a portion of said desired deposition material comprises forming ions of said desired deposition material are at a higher rate than said carrier material and applying an electric field to draw said desired deposition material toward said alloy material edge.

14. The method of claim 11, wherein providing said alloy material comprises providing a substantially circular alloy; and wherein physically separating said at least a portion of said desired deposition material to increase said concentration of said desired deposition material at said edge of said alloy material comprises physically separating a portion of said desired deposition material to form a substantially parabolic concentration curve across a diameter of said substantially circular alloy material.

15. A method of fabricating a concentration-graded alloy sputtering target, comprising:
forming a first target portion having a first concentration of a desired deposition material; and
forming at least one target portion of a second concentration of said desired deposition material about said first target portion.

16. The method of claim 15, wherein forming at least one target portion of said second concentration of said desired deposition material about the first target portion comprises forming at least one target portion about the first target portion of a second concentration of said desired deposition material which is a higher concentration than said first target portion.

17. The method of claim 15, wherein forming said first target portion comprises forming a substantially circular first target portion; and wherein forming at least one target portion about said first target portion comprises forming an annular ring about said first target portion.

18. The method of claim 15, wherein forming said first target portion comprises placing a molten or viscous alloy material having said first concentration of said desired deposition material in a first mold and allowing said alloy material to solidify.

19. The method of claim 18, wherein forming said at least one target portion about said first target portion comprises placing said first target portion in a second mold and depositing a molten or viscous alloy having said second concentration of said desired deposition material between said second mold and said first target portion; and allowing said at least one target portion about said first target portion to solidify
